(19) United States
(12) Patent Application Publication
(10) Pub. No.: US 2017/0174510 A1
(43) Pub. Date: Jun. 22, 2017

(54) METHOD OF ADDRESSING FILM LIFTOFF IN MEMS FABRICATION

(71) Applicant: Texas Instruments Incorporated, Dallas, TX (US)

(72) Inventors: Earl Vedere Atnip, Plano, TX (US); Sean Christopher O'Brien, Dallas, TX (US)

(21) Appl. No.: 15/007,626

(22) Filed: Jan. 27, 2016

Related U.S. Application Data
(60) Provisional application No. 62/268,593, filed on Dec. 17, 2015.

(51) Int. Cl. B81C 1/00; G02B 26/08

(52) U.S. Cl. CPC B81C 1/00849; G02B 26/0833; B81C 2203/0735; B81C 2201/0159; B81C 2201/013; B81C 2201/0176; B81C 2201/0181

(57) ABSTRACT

A method of fabricating a MEMS device. A first spacer is formed above a CMOS substrate containing circuitry. Vias are formed within the first spacer. A first metal is formed above the first spacer and vias and patterned to form a MEMS element. A second spacer is formed above the MEMS element and first spacer. A via is formed within the second spacer. A second metal is formed above the second spacer and the via. A capping layer is formed above the second metal. The second metal is patterned to form a second MEMS element. The device is cleaned using a developer solution while the capping layer protects the second MEMS element. The first and second spacers are removed to release the first and second MEMS elements.

### CROSS-REFERENCE TO RELATED APPLICATION

This application claims priority to U.S. Provisional Patent Application Ser. No. 62/268,593, filed Dec. 17, 2015, which is hereby fully incorporated herein by reference for all purposes.

### TECHNICAL FIELD

This relates generally to the fabrication of microelectromechanical systems (MEMS), and more particularly to fabrication of the digital micromirror device (DMD).

### BACKGROUND

A digital micromirror device (DMD), such as a Texas Instruments DLP® micromirror device, uses an array of individually positionable micromirrors to form an image onto a display panel. The array of mirrors is fabricated within the MEMS superstructure above a substrate containing CMOS circuitry.

FIG. 1 (PRIOR ART) is a cross-sectional view of a micromirror device 100, which includes a CMOS structure 104 below a MEMS superstructure 102.

A substrate 106 includes transistors 108. A first dielectric layer 110 is deposited above the transistors 108 and patterned. A first metal layer 112 is deposited above the first dielectric layer 110 and patterned. A second dielectric layer 114 is deposited above the first metal layer 112 and patterned. A second metal layer 116 is deposited above the second dielectric layer 114 and patterned. A third dielectric layer 118 is deposited above the second metal layer 116 and patterned.

A MEMS superstructure 102 is fabricated above the CMOS structure 104, with deposition of the third metal layer 120, which is deposited above the third dielectric layer 118, and patterned.

A spacer layer 122, typically a photoresist material, is deposited above the third metal layer 120. This spacer layer 122 is sacrificial and is removed at a later step. Hinge vias 124 are patterned within the spacer layer 122. A metal layer is deposited above the spacer layer 122 and within the hinge vias 124 to form the hinge 126. Another spacer layer 130, typically of a photoresist material, is deposited above the hinge 126. A mirror via 132 is patterned within the spacer layer 130, and a mirror metal is deposited above the spacer layer 130 to form a micromirror 134 and within the mirror via 132. The spacer layer 130 is also sacrificial.

The mirror via 132 may remain partially unfilled after mirror metal deposition. A small central indentation 138 remains within the reflective mirror 134 surface, above the mirror via 132, and may cause light scattering. The scattered light may contribute to a reduction in contrast ratio of the display system. The indentation 138 can be filled using a bottom anti-reflective coating (BARC) or photoresist material to improve display system contrast by reducing scattered light.

Prior to a cleaning process, photoresist remains on the micromirror device from micromirror patterning. There may be a layer of BARC below the photoresist. These layers are anchored by the indentation 138. A developer solution, such as tetramethyl ammonium hydroxide, is used to clean the micromirror 134. When the indentation 138 is filled, the stack of photoresist and BARC may no longer be anchored to the indentation. The developer solution etches the micromirror 134 and lifts off the squares of stacked photoresist and BARC during cleaning and re-deposits these squares randomly across the wafer that includes micromirror devices. These squares may cause a reduction in device lifetime and process control, and increased yield loss and device failure due to defects.

FIG. 2 (PRIOR ART) shows a top-down image 200 of a finished wafer 202 with micromirror array 202.

Squares 204 of photoresist and BARC are scattered randomly across the array 202. The squares 204 have delaminated from above the micromirror 206 surface and re-deposited across the array 202.

FIG. 3 (PRIOR ART) shows another image 300 of a micromirror array 302.

A micromirror 304 has delaminated and re-deposited across the array 302.

### SUMMARY

A method of addressing delamination of photoresist and anti-reflective layers in MEMS fabrication is provided. In a method of fabricating a MEMS device, a first spacer is formed above a CMOS substrate containing circuitry. Vias are formed within the first spacer. A first metal is formed above the first spacer and vias and patterned to form a first MEMS element. A second spacer is formed above the first MEMS element and first spacer. A via is formed within the second spacer. A second metal is formed above the second spacer and the via. A capping layer is formed above the second metal. The second metal is patterned to form a second MEMS element. The device is cleaned using a developer solution while the capping layer protects the second MEMS element. The first and second spacer are removed to release the first and second MEMS elements.

### BRIEF DESCRIPTION OF THE DRAWINGS

Example embodiments are described with reference to accompanying drawings, wherein:

FIG. 1 (Prior Art) is a cross-sectional view of a micromirror.

FIG. 2 (Prior Art) is a top view of delaminated squares re-deposited above an array of micromirrors.

FIG. 3 (Prior Art) is a top view of delaminated squares re-deposited above the periphery of an array of micromirrors.

FIG. 4 is a cross-sectional image of a micromirror.

FIGS. 5A through 5E illustrate cross-sections of a micromirror during fabrication.

FIG. 6 depicts an image of an intersection of micromirrors.

FIG. 7 depicts a wafer level image.

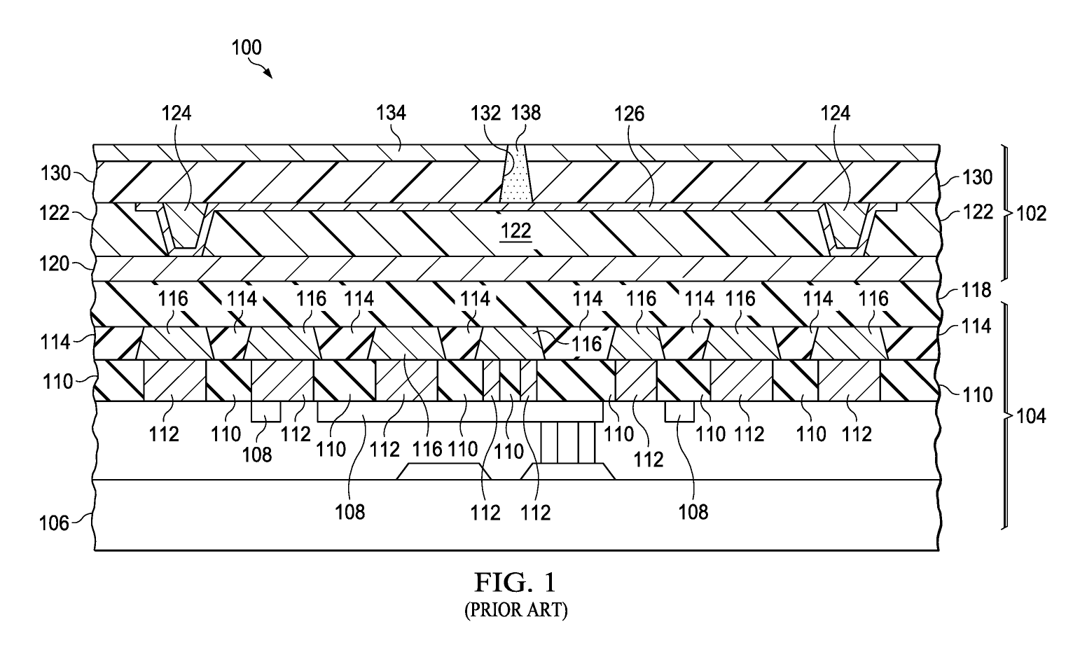

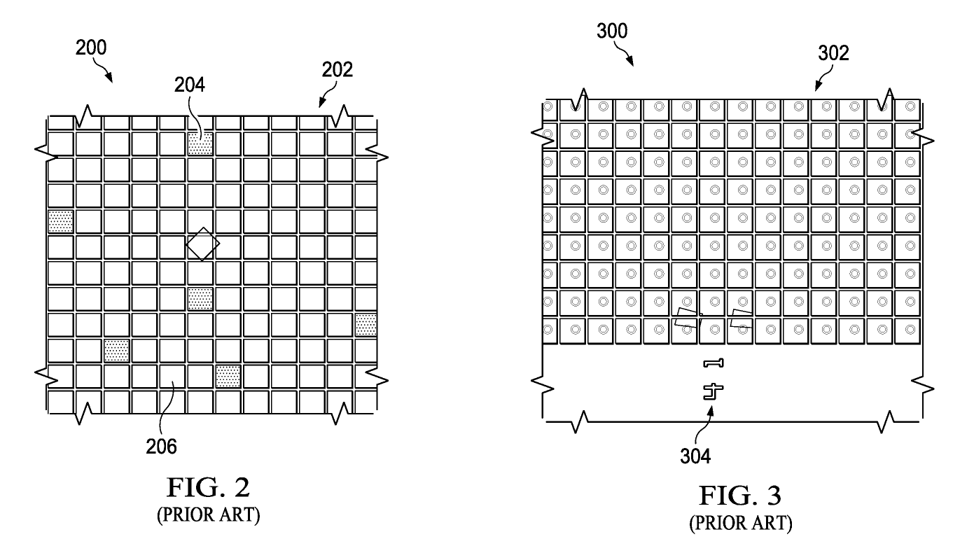

### DETAILED DESCRIPTION OF EXAMPLE EMBODIMENTS

The steps described below are typically undertaken on a wafer level scale, with multiple instances of the illustrated structures simultaneously formed to define arrays of such structures formed at respective die areas of corresponding simultaneously formed DMDs. Although discussed in terms of a DMD, aspects of the example embodiments may be applied to other MEMS devices and elements.

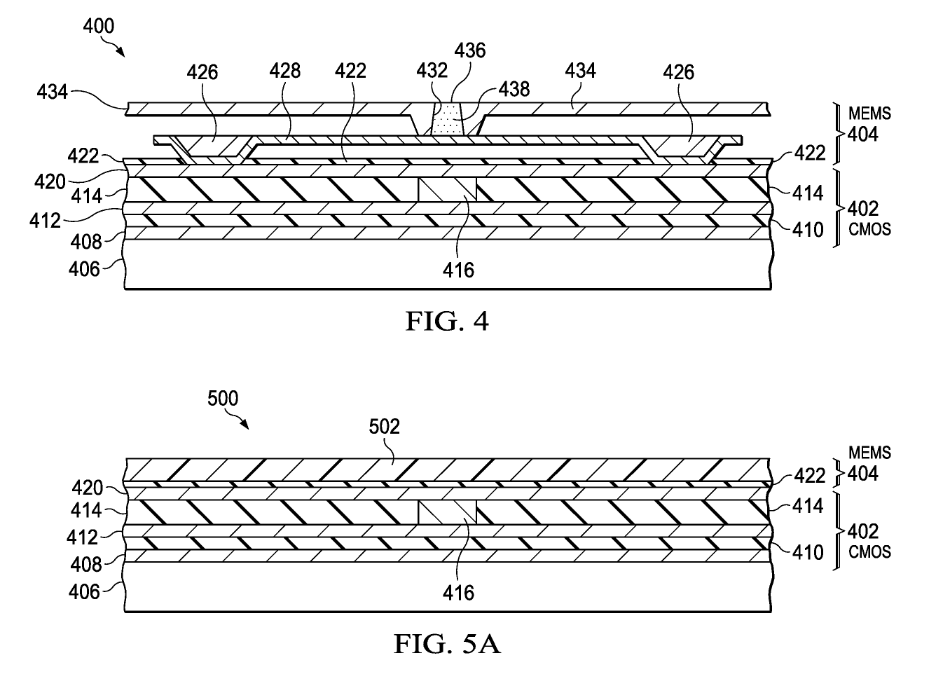

FIG. 4 illustrates a micromirror 400, including a CMOS portion 402 and a MEMS portion 404.

The CMOS portion 402 includes a substrate 406 with transistors. As an example, a first metal layer 408 may be deposited above the substrate 406 and transistors and patterned. A first dielectric layer 410 may be deposited above the patterned metal layer 408. A second metal layer 412 may deposited above the dielectric layer 410 and patterned. A second dielectric 414 may deposited above the patterned metal layer 412. A first via 416 is patterned within the dielectric layer 414 and filled with a metal such as tungsten. A third metal 420 is deposited above the dielectric layer 414. An anti-reflective layer 422 of one or more films is deposited above the metal layer 420. The anti-reflective layer 422 aids in reducing light reflectance from the metal layer 420 below and in improving contrast of the micromirror device 400.

A layer, typically of a metal such as titanium, is deposited to form hinge vias 426 and a hinge 428 above the third metal 420. A metal layer is deposited to form a centrally placed mirror via 432 above the hinge 428. The mirror via 432 and micromirror 434 include a reflective material, such as an alloy including 99% aluminum and 1% titanium. A central indentation 436 within the top surface of the micromirror 434 remains after deposition of the metal within the mirror via 432 opening, and is filled with an antireflective BARC layer 438 to improve system contrast.

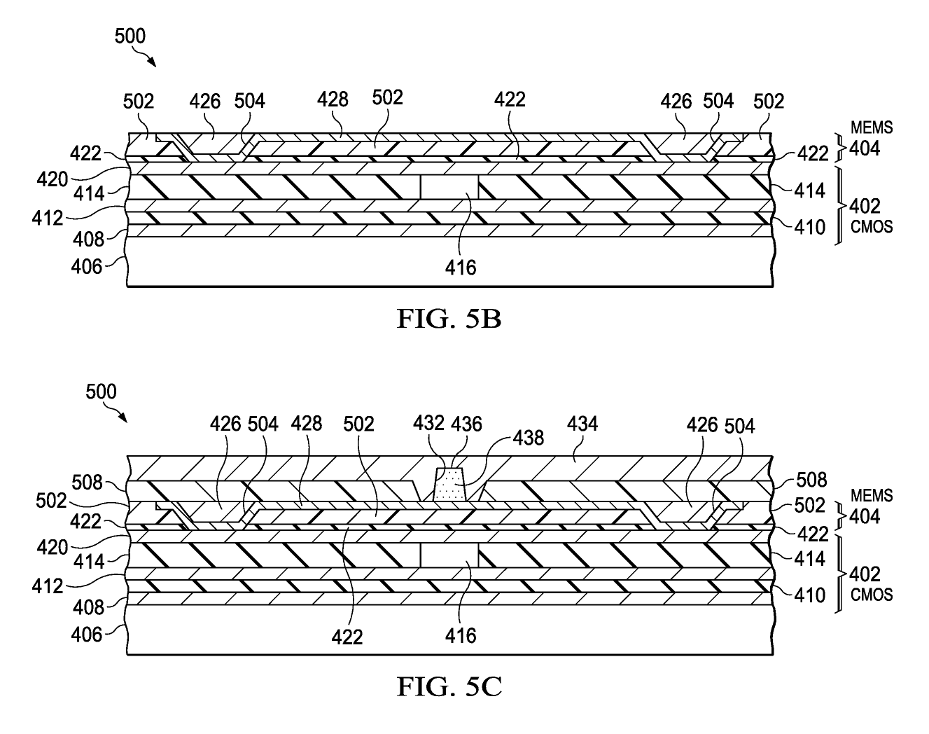

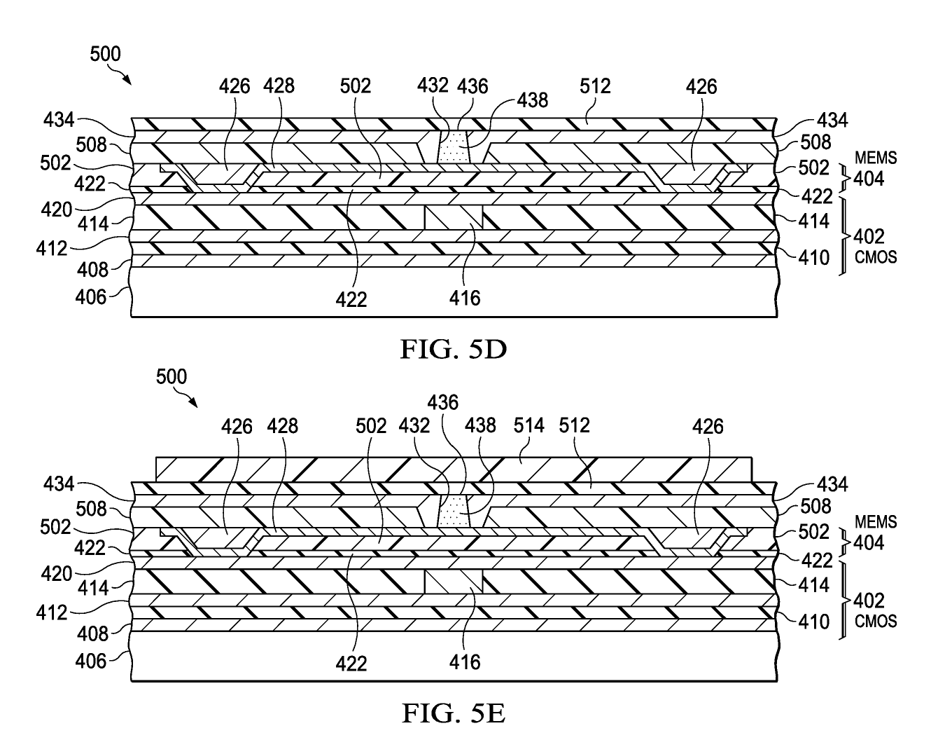

FIGS. 5A through 5E illustrate cross-sections (indicated generally at 500) of the micromirror 400 during fabrication.

FIG. 5A illustrates fabrication of the MEMS portion 404 of the micromirror above the CMOS portion 402.

After deposition of the anti-reflective layer 422, a spacer layer 502 is deposited above the anti-reflective layer 422. Layer 502 is a sacrificial layer including a material such as photoresist and is removed at a later step.

In FIG. 5B, the spacer layer 502 is patterned to form vias 504. A metal is deposited within the patterned vias 504 to form the hinge vias 426 and above the spacer layer 502 to form the hinge 428.

In FIG. 5C, a spacer layer 508, typically a material such as photoresist, is deposited above the hinge 428. A via is patterned centrally within the layer 508 to form the mirror via 432. A mirror metal is deposited on the spacer layer 508 to form the micromirror 434 and within the via to form the mirror via 432. A central indentation 436 results from deposition of the mirror metal in the mirror via 432. The indentation 436 is filled with an anti-reflective layer 438.

FIG. 5D shows a capping layer 512 deposited above the mirror 434 surface. The capping layer 512 may be deposited using a process such as chemical vapor deposition or sputtering. The layer 512 includes a dielectric such as silicon oxynitride, nitride, or oxide, which is sacrificial, or a metal oxide such as a titanium oxide. The thickness of layer 512 is approximately 10 to 100 Angstroms and limited by the amount of tensile stress placed on the mirror 434 surface by the layer 512 and by the time required to ash it if the layer 512 is a sacrificial dielectric.

In an example embodiment, the layer 512 is an oxynitride film of thickness of about 100 Angstroms deposited using chemical vapor deposition. The layer 512 is sacrificial and is removed when the spacer layers 502 and 508 are removed using an O₂ and CF₄ ash during undercut. The layer 512 blocks the developer solution of a subsequent cleaning process from coming in contact with layer 434 and lifting the photoresist and BARC layered squares.

In FIG. 5E, a layer 514 such as a photoresist (or ARC and resist) is deposited above layer 512. Layer 514 is patterned and used to etch the mirror metal to form individual mirror 434 structures. After the etch, a developer solution including tetramethyl ammonium hydroxide is used to clean the device 500. During this clean, layer 512 protects the mirror 434 from the developer solution. The layer 514 is then removed.

The developer cleaning process can delaminate patterned areas of layer 514 (BARC and photoresist) from the device 500 surface. These delaminated portions of layer 514 can redeposit above the mirrors 436 and across scribe lines to form defects. The protective layer 512 forms an adhesive for the BARC and photoresist of layer 514 as well as a protective shield against re-deposition of delaminated areas of layer 514 onto the mirror 434 surface.

The spacer layers 502 and 508 are removed using an oxygen ash to release the hinge 428 and micromirror 434. The hinge vias 426 forms a free-standing support for the hinge 428, and mirror via 432 forms a free-standing support for the micromirror 434 as shown in FIG. 4. This ash may also be used to remove layer 512.

The described methodology may offer many advantages.

The layer 512 forms a protective layer on the mirror metal layer surface, which prevents the chemical and physical reactants from the developer cleaning process from coming in contact with the mirror metal.

The layer 512 may be a sacrificial dielectric layer and removed in an oxygen based ash.

The layer 512 may be a metal oxide, which remains on the surface of layer 434.

The layer 512 addresses the delamination of photoresist and BARC layers from the mirror surface.

Experimental data has shown that the layer 512 is effective against delamination of photoresist and BARC layers and reduces yield loss.

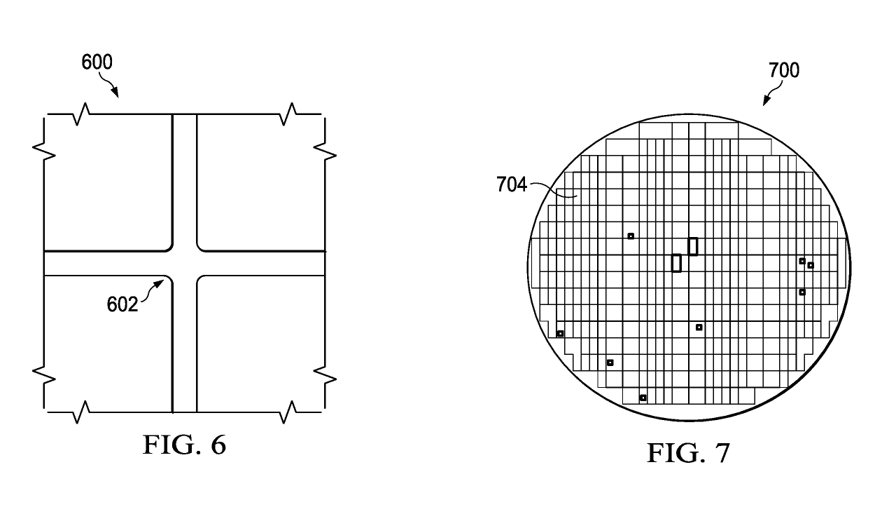

FIG. 6 shows an image 600 of an intersection of micromirrors 602. The image 600 demonstrates the lack of delaminated squares 604 across the intersection 602.

FIG. 7 shows a wafer level image 700. The wafer 702 includes multiple micromirror devices 704. The image demonstrates the lack of delaminated squares 706 across the wafer 702.

Modifications are possible in the described example embodiments, and other embodiments are possible, within the scope of the claims.

1. A method of fabricating a digital micromirror device, the method comprising:
forming a first spacer above a CMOS substrate containing circuitry;
forming hinge vias within the first spacer;
depositing a first metal above the first spacer and hinge vias and patterning the first metal to form a hinge;
forming a second spacer above the hinge and first spacer;
forming a mirror via within the second spacer;
depositing a second metal above the second spacer and the mirror via;
forming a sacrificial dielectric capping layer on a surface of the second metal;
patterning the second metal to form a mirror;
cleaning the device using a developer solution; and
removing the first and second spacer layers to release the hinge and mirror.

2. A method of fabricating a digital micromirror device, the method comprising:
forming a first spacer above a CMOS substrate containing circuitry and patterning the first spacer to form openings for the hinge vias;
depositing a hinge liner metal above the first spacer and hinge vias to form a hinge via liner;
depositing a hinge via plug material above the hinge via liner to form a hinge via plug;
removing hinge via liner metal and hinge via plug material from above the first spacer;
depositing a hinge metal above the first spacer and hinge vias and patterning the hinge metal to form a hinge;
forming a second spacer above the hinge and first spacer and patterning the second spacer to form a mirror via;
depositing a mirror metal above the second spacer and mirror;
depositing an anti-reflective layer within a central indentation in the mirror via;
forming a sacrificial dielectric capping layer on a surface of the mirror metal;
depositing, patterning and exposing patterning layers above the capping layer;
etching the mirror metal to form a mirror;
cleaning the device using a developer solution;
removing patterning layers using a descum process; and
removing the first and second spacer layers to release the hinge and mirror.

3. The method of claim 2, wherein the capping layer is deposited using chemical vapor deposition.

4. The method of claim 2, wherein a thickness of the capping layer is 10 to 100 Angstroms.

5. The method of claim 2, wherein the capping layer comprises an oxynitride.

6. The method of claim 2, wherein the capping layer is deposited using sputtering.

7. The method of claim 2, wherein at least a majority of the capping layer is removed using an ash process.

8. The method of claim 2, wherein the capping layer comprises a metal oxide.

9. The method of claim 7, wherein a portion of the capping layer is not removed from the mirror metal surface.

10. A method of fabricating a microelectromechanical systems (MEMS) device, the method comprising:
forming a first spacer above a CMOS substrate containing circuitry;
forming vias within the first spacer;
depositing a first metal above the first spacer and vias and patterning the first metal to form a first MEMS element;
forming a second spacer above the first MEMS element and first spacer;
forming a via within the second spacer;
depositing a second metal above the second spacer and the via;
forming a sacrificial dielectric capping layer on a surface of the second metal;
patterning the second metal to form a second MEMS element;
cleaning the device using a developer solution; and
removing the first and second spacer layers to release the first and second MEMS elements.

11. The method of claim 10, wherein the capping layer is deposited using chemical vapor deposition.

12. The method of claim 10, wherein the capping layer is deposited using sputtering.

13. The method of claim 10, wherein a thickness of the capping layer is 10 to 100 Angstroms.

14. The method of claim 10, wherein the capping layer comprises an oxynitride.

15. (canceled).

16. The method of claim 10, wherein at least a majority of the capping layer is removed using an ash process.

17. The method of claim 10, wherein the capping layer comprises a metal oxide.

18. The method of claim 16, wherein a portion of the capping layer is not removed from the second metal surface.

19. The method of claim 1, wherein the capping layer is deposited using chemical vapor deposition.

20. The method of claim 1, wherein the capping layer is deposited using sputtering.

21. The method of claim 1, wherein a thickness of the capping layer is 10 to 100 Angstroms.

22. The method of claim 1, wherein the capping layer comprises an oxynitride.

23. The method of claim 1, wherein the capping layer comprises a metal oxide.

24. The method of claim 1, wherein at least a majority of the capping layer is removed using an ash process.

25. The method of claim 8, wherein a portion of the capping layer is not removed from the mirror metal surface.
